(19) United States
(12) Patent Application Publication
(10) Pub. No.: US 2017/0268734 A1
(43) Pub. Date: Sep. 21, 2017

(54) LIGHT EMITTING DEVICE AND LIGHTING DEVICE

(71) Applicant: SHARP KABUSHIKI KAISHA, Sakai City, Osaka (JP)

(72) Inventors: Yoshihiro KAWAGUCHI, Sakai City, Osaka (JP); Tomokazu NADA, Sakai City, Osaka (JP); Makoto MATSUDA, Sakai City, Osaka (JP); Hiroaki ONUMA, Sakai City, Osaka (JP); Osamu JINUSHI, Sakai City, Osaka (JP); Toshio HATA, Sakai City, Osaka (JP)

(21) Appl. No.: 15/528,595

(22) PCT Filed: Aug. 25, 2015
(86) PCT No.: PCT/JP2015/073809

§ 371 Date: May 22, 2017

(30) Foreign Application Priority Data
Nov. 28, 2014 (JP) 2014-241653

(51) Int. Cl. F21K 9/64; H05B 33/08; H01L 25/13; F21V 7/22

(52) U.S. Cl. CPC F21K 9/64; F21V 7/22; H05B 33/0845; H01L 25/13; F21Y 2115/10

(57) ABSTRACT

A light emitting device that can adjust a color temperature by using power supply from a single power source and a lighting device including the light emitting device are provided. A light emitting device includes a reflector formed of a housing having an opening at an upper portion, an anode electrode terminal and a cathode electrode terminal that are disposed on a side wall or a bottom surface of the housing, and a first light-emitting portion and a second light-emitting portion that are arranged in parallel inside the reflector so as to be electrically connected to the anode electrode terminal and the cathode electrode terminal and that are adjacent to each other. The first light-emitting portion includes a first resistance member. The color temperature of light emitted from an entire light-emitting portion including the first light-emitting portion and the second light-emitting portion can be adjusted.

### TECHNICAL FIELD

The present invention relates to a light emitting device and a lighting device that enable a color temperature to be adjusted.

### BACKGROUND ART

A halogen lamp exhibits an excellent color rendering property because the energy distribution thereof approximates closely to that of a perfect radiator. The color temperature of light emitted from the halogen lamp can be changed in accordance with the magnitude of power supplied to the halogen lamp, and accordingly, the halogen lamp is used as a visible light source. The halogen lamp, however, has problems in that the temperature of the halogen lamp becomes very high because the halogen lamp emits infrared light, and the halogen lamp needs a reflector for preventing infrared light radiation, has a lifetime shorter than that of a LED, and has a large power consumption. In view of this, white light emitting devices with light-emitting diodes (LED) that generate less heat and have a longer lifetime have been developed.

PTL 1 (Japanese Unexamined Patent Application Publication No. 2009-224656) discloses a light emitting device including a base having a recessed portion having inclined surfaces that are formed as bottom surfaces and that are inclined in directions in which the inclined surfaces face each other, light-emitting elements disposed on the respective inclined surfaces, and wavelength-converting members that cover the respective light-emitting elements and that convert light emitted from the respective light-emitting elements into light with different wavelengths.

PTL 2 (Japanese Unexamined Patent Application Publication No. 2011-159809) discloses a white light emitting device having a first white-light-generating system that is formed of an ultraviolet or violet LED chip and a phosphor and that generates first white light and a second white-light-generating system that is formed of a blue LED chip and a phosphor and that generates second white light, in which the first and second white-light-generating systems are spatially separated from each other, the color temperature of the first white light is lower than the color temperature of the second white light, and mixed light including the first white light and the second white light can be emitted.

PTL 3 (Japanese Unexamined Patent Application Publication No. 2011-222723) discloses a light emitting device including a light source that includes first and second light-emitting diodes having different luminescent colors and connected to each other in parallel and that emits, as emitted light, mixed color light from the first and second light-emitting diodes when a drive voltage is applied across both ends, in which the light source is connected to the first light-emitting diode in series such that variation characteristics of the color temperature of the emitted light with respect to a variation in the luminous flux of the emitted light are desired characteristics in a state where the drive voltage is applied and the light-emitting diodes illuminate, and a resistor that differentiates the variation characteristics of forward current with respect to a variation in the drive voltage between the first light-emitting diode and the second light-emitting diode is provided.

PTL 4 (Japanese Unexamined Patent Application Publication No. 2012-64925) discloses a LED light emitting device that emits combined light created by combining visible light emitted from a first LED and visible light emitted from a second LED, in which a drive-controlling unit controls a first drive current supplied to the first LED and a second drive current supplied to the second LED so that the luminescent color can be clearly varied over the entire variation range of the luminescent color, and a clearly distinguishable luminescent color can be achieved in an intermediate area within the variation range of the luminescent color.

### CITATION LIST

### Patent Literature

PTL 1: Japanese Unexamined Patent Application Publication No. 2009-224656

PTL 2: Japanese Unexamined Patent Application Publication No. 2011-159809

PTL 3: Japanese Unexamined Patent Application Publication No. 2011-222723

PTL 4: Japanese Unexamined Patent Application Publication No. 2012-064925

### SUMMARY OF INVENTION

### Technical Problem

In the related art in PTL 1 and PTL 2, power is supplied from different power sources to the light-emitting elements, and accordingly, there are problems in that wiring patterns are needed, and the structure of the light emitting devices is complex.

In the related art in PTL 3, the light-emitting diodes of red and orange luminescent colors are used, the temperature characteristics and lifetime of the light-emitting diodes differ from those of a light-emitting diode of a blue luminescent color, and accordingly, there is a problem in that the mixed light color varies. In addition, a substrate circuit is required to arrange two kinds of the light-emitting diodes thereon, and there are problems in that a light-emitting portion is large and it is difficult for a uniformly mixed color to be achieved near the light-emitting portion.

In the related art in PTL 4, circuits are required to drive respective elements, and there is a problem in that the structure of the light emitting device is complex, as in PTL 1 and PTL 2.

The present invention has been accomplished to solve the above problems, and it is an object of the present invention to provide a light emitting device that can adjust the color temperature by using power supply from a single power source, and a lighting device including the light emitting device.

### Solution to Problem

(1) The present invention provides a light emitting device including a reflector formed of a housing having an opening at an upper portion, an anode electrode terminal and a cathode electrode terminal that are disposed on a side wall or a bottom surface of the housing, and a first light-emitting portion and a second light-emitting portion that are arranged in parallel inside the reflector so as to be electrically connected to the anode electrode terminal and the cathode electrode terminal and that are adjacent to each other. The first light-emitting portion includes a first resistance member. A color temperature of light emitted from an entire light-emitting portion including the first light-emitting portion and the second light-emitting portion can be adjusted.

(2) It is preferable that, in the light emitting device according to the present invention, the first light-emitting portion and the second light-emitting portion be each arranged on a lead frame or a ceramic and the first light-emitting portion and the second light-emitting portion each include a LED element that emits blue light, a translucent resin, and at least two kinds of phosphors.

(3) The light emitting device according to the present invention preferably includes an electrostatic capacity member arranged in parallel with the first light-emitting portion and the second light-emitting portion, and a second resistance member arranged in series with the first light-emitting portion and the second light-emitting portion.

(4) In the light emitting device according to the present invention, the second resistance member is preferably a resistor or an inductor.

(5) The present invention provides a lighting device including the light emitting device in any one of the above (1) to (4), and a PWM signal type dimmer electrically connected to the light emitting device.

### Advantageous Effects of Invention

The present invention can provide a light emitting device that can adjust the color temperature by using power supply from a single power source and a lighting device including the light emitting device.

### BRIEF DESCRIPTION OF DRAWINGS

FIG. 1 is a schematic plan view of a light emitting device according to a first embodiment of the present invention.

FIG. 2 is a perspective view of the light emitting device in FIG. 1.

FIG. 3 is a schematic circuit diagram of the light emitting device in FIG. 1.

FIG. 4 is a perspective view of the light emitting device in FIG. 1.

FIG. 5 is a graph illustrating the relationship between the relative luminous flux and color temperature of light emitted from the light emitting device.

FIG. 6 is a perspective view of a modification to the light emitting device according to the first embodiment of the present invention.

FIG. 7 is a schematic perspective view of a light emitting device according to a second embodiment of the present invention.

FIG. 8 is a schematic circuit diagram of a lighting device that uses the light emitting device in FIG. 7.

FIG. 9 is a graph illustrating the relationship between the relative luminous flux and color temperature of light emitted from the light emitting device.

FIGS. 10(a) to (c) illustrate D/A conversion of a pulse signal from a PWM signal type dimmer.

FIG. 11 is a schematic perspective view of a light emitting device according to a third embodiment of the present invention.

FIG. 12 is a perspective view of a modification to the light emitting device according to the third embodiment of the present invention.

FIG. 13 is a plan view of the modification to the light emitting device according to the third embodiment of the present invention.

### DESCRIPTION OF EMBODIMENTS

A light emitting device and a lighting device according to an embodiment of the present invention will hereinafter be described with reference to the drawings. In the drawings, like symbols designate like or corresponding components. The dimensional relationships of, for example, a length, a width, a thickness, and a depth are appropriately changed for clarification and simplification of the drawings, and the actual dimensional relationships are not illustrated.

### First Embodiment

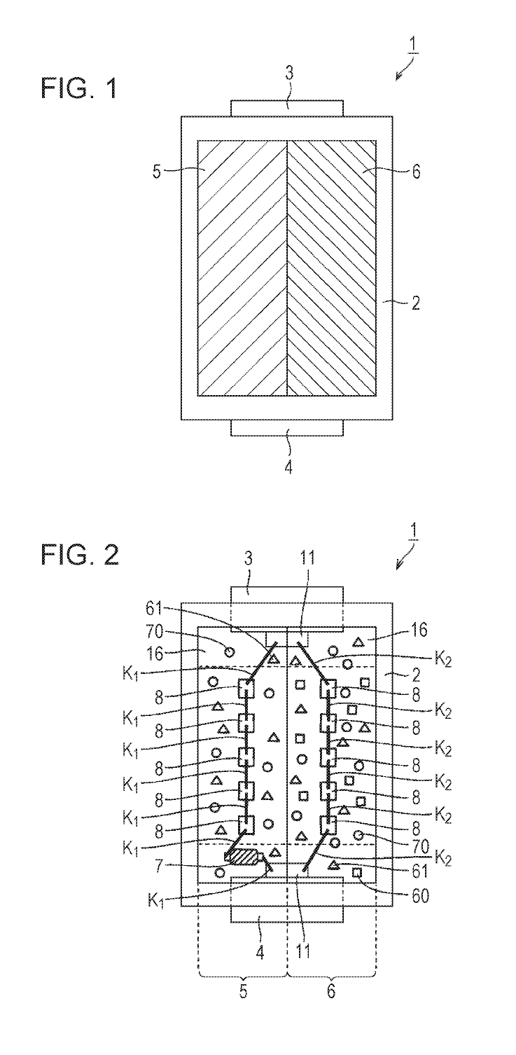

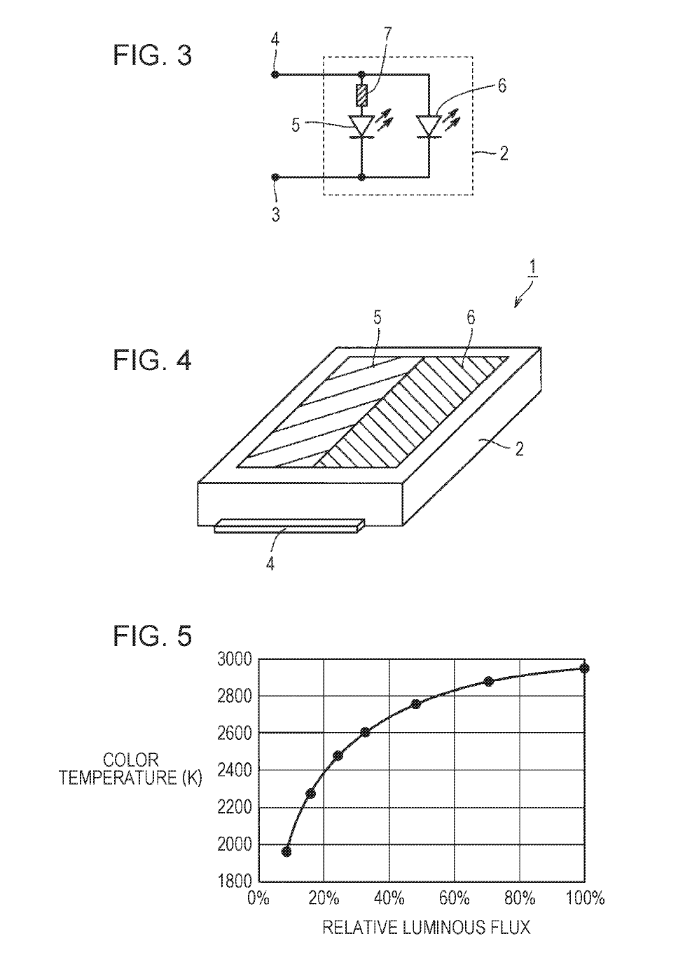

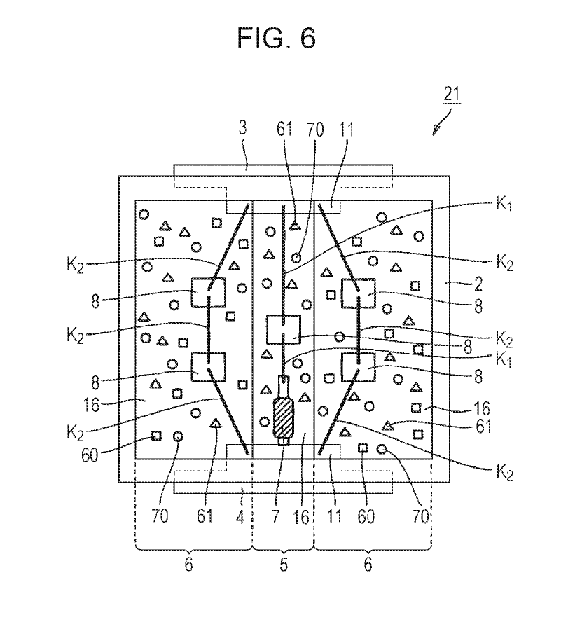

A light emitting device according to a first embodiment will be described with reference to FIG. 1 to FIG. 4 and FIG. 6. FIG. 1 is a schematic plan view of the light emitting device according to the first embodiment of the present invention. FIG. 2 is a perspective view of the light emitting device in FIG. 1. FIG. 3 is a schematic circuit diagram of the light emitting device in FIG. 1. FIG. 4 is a perspective view of the light emitting device in FIG. 1. FIG. 6 is a perspective view of a modification to the light emitting device according to the first embodiment and illustrates the light emitting device that uses, for example, a ceramic substrate.

As illustrated in FIG. 1 to FIG. 4, a light emitting device 1 includes a reflector 2 formed of a housing having an opening at an upper portion, an anode electrode terminal 3 and a cathode electrode terminal 4 that are disposed on the side wall of the reflector 2, and a first light-emitting portion 5 and a second light-emitting portion 6 that are arranged in parallel inside the reflector 2 so as to be electrically connected to the anode electrode terminal 3 and the cathode electrode terminal 4 and that are adjacent to each other. The first light-emitting portion 5 includes a first resistance member 7. The color temperature of light emitted from the entire light-emitting portion including the first light-emitting portion 5 and the second light-emitting portion 6 can be adjusted.

As illustrated in FIG. 2, the first light-emitting portion 5 includes the first resistance member 7, second red phosphors 61, green phosphors 70, LED elements 8, and a translucent resin 16. The anode electrode terminal 3, the LED elements 8, the first resistance member 7, and the cathode electrode terminal 4 are electrically connected in this order.

As illustrated in FIG. 2, the second light-emitting portion 6 includes first red phosphors 60, second red phosphors 61, green phosphors 70, LED elements 8, and a translucent resin 16. The anode electrode terminal 3, the LED elements 8, and the cathode electrode terminal 4 are electrically connected in this order.

In the light emitting device 1, the first light-emitting portion 5 and the second light-emitting portion 6 illuminate by using power supply from a single power source. Light emitted from the first light-emitting portion 5 and light emitted from the second light-emitting portion 6 are mixed and emitted as light from the light emitting device 1 to the outside.

In the case where a ratio between the electric current flowing to the first light-emitting portion 5 and the electric current flowing to the second light-emitting portion 6 is changed, a luminous flux ratio between the light-emitting portions changes, although the color temperature of light emitted from the first light-emitting portion 5 and from the second light-emitting portion 6 does not change. Accordingly, the color temperature of light from the entire light-emitting portion, which is mixed light of light emitted from the first light-emitting portion 5 and the second light-emitting portion 6, can be changed.

### (Reflector)

In the light emitting device 1, the first light-emitting portion 5 and the second light-emitting portion 6 are disposed inside the reflector 2. Thus, light emitted from the LED elements 8, the red phosphors 60 and 61, and the green phosphors 70 to the side of the light emitting device is diffusely reflected from a surface of the reflector and distributed in the axial direction of the light emitting device. Accordingly, the emission intensity of the light emitting device along the axis increases, and a light emitting device having excellent directivity can be obtained.

The reflector is formed of the housing having the opening at the upper portion. At least the inner side surface of the housing is made of a material having excellent light reflectivity or coated with a material having excellent light reflectivity. The material of the reflector may be, for example, a polyamide resin, a liquid-crystal polymer, or silicone.

The shape of the reflector is not particularly limited, provided that the reflector is formed of the housing having the opening at the upper portion and enables light emitted from the LED elements to be distributed in the axial direction of the light emitting device. For example, the reflector may be hollowed from a rectangular cuboid into a cone, hollowed from a column into a cone, or hollowed from a rectangular cuboid into a convex shape (semi-cylinder).

The size of the reflector can be appropriately selected in accordance with the use of a lighting apparatus to be used. Regarding the size of the opening, the opening may be formed, for example, in a rectangular shape whose sides are each no less than 2 mm and no more than 20 mm, preferably, no less than 3 mm and no more than 6 mm, or a circular shape whose diameter is no less than 2 mm and no more than 20 mm, preferably, no less than 3 mm and no more than 6 mm. The depth of a space in the housing may be, for example, no less than 1 mm and no more than 5 mm.

### (Anode Electrode Terminal, Cathode Electrode Terminal, Lead)

The anode electrode terminal 3 and the cathode electrode terminal 4 are electrodes for external connection (for example, for power supply) and made of a material such as Ag—Pt. At least a part of the anode electrode terminal 3 and a part of the cathode electrode terminal 4 are exposed to the outside of the reflector 2. Inside the reflector 2, the anode electrode terminal 3 and the cathode electrode terminal 4 are connected to corresponding leads 11. The leads 11 are electrically connected to the light-emitting elements with wires K₁ and K₂ interposed therebetween.

The leads 11 are formed of, for example, a copper alloy, and the surface is formed of, for example, Ag plating.

### (First Light-Emitting Portion, Second Light-Emitting Portion)

The first light-emitting portion 5 and the second light-emitting portion 6 (a portion including both is also referred to below as a “light-emitting portion”) include the translucent resin 16, and the green phosphors and the red phosphors that are uniformly dispersed in the translucent resin.

In the light emitting device illustrated in FIG. 1, the first light-emitting portion 5 and the second light-emitting portion 6 are arranged inside the reflector 2 whose opening is rectangular. In the light emitting device illustrated in FIG. 2, a section of the bottom surface that is interposed between two dashed lines inside the opening of the reflector 2 corresponds to a lead frame, and a section of the bottom surface that is interposed between each of the dashed lines and a short side of the opening of the reflector is made of the same resin material as the reflector.

The first light-emitting portion 5 is located in a first section of two sections into which the rectangular opening of the reflector 2 is divided by a straight line, and the second light-emitting portion 6 is located in a second section. In FIG. 1, the first light-emitting portion 5 and the second light-emitting portion 6 are adjacent to each other along a borderline. Accordingly, light emitted from the first light-emitting portion 5 and light emitted from the second light-emitting portion 6 are likely to be mixed, and the entire light-emitting portion can emit light with a more uniform color temperature. Although the first light-emitting portion 5 and the second light-emitting portion 6 are preferably arranged so as to be adjacent to each other, the first light-emitting portion and the second light-emitting portion are not necessarily in contact with each other, provided that light emitted from the first light-emitting portion and light emitted from the second light-emitting portion can be mixed. In this case, the first light-emitting portion and the second light-emitting portion are preferably arranged close to each other to such an extent that the light emitted from each light-emitting portion can be sufficiently mixed.

The shape of the upper surface of the entire light-emitting portion including the first light-emitting portion and the second light-emitting portion is not limited to a rectangle as illustrated in FIG. 1, provided that light emitted from the first light-emitting portion and light emitted from the second light-emitting portion can be mixed. For example, the shape of the upper surface of the entire light-emitting portion may be an arbitrary shape such as a circle, an eclipse, or a polygon. Also, the shape of the first light-emitting portion and second light-emitting portion located inside the entire light-emitting portion is not particularly limited. For example, a preferable shape is such that the surface areas of the first light-emitting portion and the second light-emitting portion are equal. The surface areas of the first light-emitting portion and the second light-emitting portion may be different, provided that the color temperature of light emitted from the first light-emitting portion and light emitted from the second light-emitting portion can be adjusted.

The arrangement of the first light-emitting portion and the second light-emitting portion is not particularly limited, provided that light emitted from the first light-emitting portion and light emitted from the second light-emitting portion can be mixed. For example, as illustrated in FIG. 6, the rectangular opening of the reflector may be divided parallel into three sections, the first light-emitting portion 5 may be located in the central section, and the second light-emitting portions 6 may be located in two sections on both sides. The first light-emitting portion may be formed in a circular shape, and the second light-emitting portion may be formed in a torus shape so as to encompass the outer circumference of the first light-emitting portion. Thus, light emitted from the first light-emitting portion and light emitted from the second light-emitting portion are likely to be mixed, and the entire light-emitting portion can emit light with a more uniform color temperature.

At the light-emitting portion, part of primary light (for example, blue light) emitted from the LED elements 8 is converted into green light and red light by using the green phosphors and the red phosphors. Thus, the light emitting device according to the present embodiment emits mixed light of the primary light, the green light, and the red light and preferably emits white light. A mixing ratio of the green phosphors and the red phosphors is not particularly limited and is preferably determined such that desired characteristics are achieved.

The luminous flux of light emitted from the first light-emitting portion and the luminous flux of light emitted from the second light-emitting portion can be adjusted in a manner in which the value of the electric current flowing through the first light-emitting portion and the second light-emitting portion is changed.

In the case where the value of the electric current flowing through the light-emitting portion is regarded as a rated current value, the color temperature (also referred to below as Tcmax) of mixed light of light emitted from the first light-emitting portion and light emitted from the second light-emitting portion, which is emitted from the entire light emitting device, is preferably 2700 K to 6500 K. In the case where the value of the electric current is less than the rated current value, the luminous flux of light emitted from the first light-emitting portion and the second light-emitting portion decreases, the luminous flux of light emitted from the entire light emitting device (light-emitting portion) decreases, and the color temperature decreases. From the viewpoint of achieving a wide range of color temperatures, it is preferable that the luminous flux of light emitted from the entire light emitting device be 100% in the case where the value of the electric current flowing through the light-emitting portion is equal to the rated current value, and the color temperature of the light emitted from the entire light emitting device be lower than the Tcmax by 300 K or more in the case where the value of the electric current is decreased to adjust the luminous flux of the light emitted from the entire light emitting device to be 20%.

### (Resistance Member)

The first light-emitting portion 5 includes the first resistance member 7. Specifically, the resistance member 7 is connected, in series with the LED elements 8, to a wiring including the wires K₁ that electrically connect the anode electrode terminal 3 and the cathode electrode terminal 4 to each other. The value of the electric current flowing through the first light-emitting portion and the second light-emitting portion can be adjusted in a manner in which the resistance value is changed. The change in the value of the electric current flowing through the first light-emitting portion and the second light-emitting portion changes the luminous flux of light emitted from the LED elements connected to the first light-emitting portion or the second light-emitting portion, changing the luminous flux of light emitted from the first light-emitting portion and the second light-emitting portion. Since the change in the luminous flux of light emitted from the light-emitting portion changes the color temperature of the light, the color temperature of light emitted from the entire light emitting device can be adjusted in a manner in which the resistance value is changed.

A chip resistor or a print resistor may be used as a resistor.

According to the first embodiment, a resistor is connected to only the first light-emitting portion. However, a resistor may be connected also to the second light-emitting portion. In this case, the resistors connected to the respective light-emitting portions are selected such that the resistance value of the first light-emitting portion is larger than the resistance value of the second light-emitting portion.

### (LED Element)

The LED elements are preferably LED elements that emit light including light of a blue component that has a peak emission wavelength in a blue range (range in which the wavelength is no less than 430 nm and no more than 480 nm). In the case where a light-emitting element whose peak emission wavelength is less than 430 nm is used, a contribution ratio of a blue light component with respect to light from the light emitting device decreases. Accordingly, in some cases, the color rendering property becomes worse, and the utility of the light emitting device reduces. In some cases where a LED element whose peak emission wavelength exceeds 480 nm is used, the utility of the light emitting device reduces. In particular, an InGaN LED element has a reduced quantum efficiency, and accordingly, the utility of the light emitting device greatly reduces.

Each LED element is preferably an InGaN LED element. An example of the LED element may include an LED element whose peak emission wavelength is close to 450 nm. The “InGaN LED element” means an LED element in which a light-emitting layer is an InGaN layer.

Each LED element has a structure that emits light from the upper surface thereof. The LED element includes an electrode pad for connecting the adjoining LED elements to each other with wires on the surface interposed therebetween and an electrode pad for connecting the LED element to a wiring pattern or an electrode terminal.

### (Translucent Resin)

The translucent resin contained in the light-emitting portion is not limited, provided that the translucent resin is a resin having translucency. For example, the translucent resin is preferably an epoxy resin, a silicone resin, or a urea-formaldehyde resin.

### (Red Phosphor)

The red phosphors are excited by primary light emitted from the LED elements and emit light whose peak emission wavelength is in a red range. The red phosphors do not illuminate within a wavelength range of 700 nm or more and do not absorb light within a wavelength range of no less than 550 nm and no more than 600 nm. The phrase “the red phosphors do not illuminate within a wavelength range of 700 nm or more” means that the emission intensity of the red phosphors within a wavelength range of 700 nm or more at a temperature of 300 K or more is 1/100 or less of the emission intensity of the red phosphors at the peak emission wavelength. The phrase “the red phosphors do not absorb light within a wavelength range of no less than 550 nm and no more than 600 nm” means that the integrated value of the excitation spectrum of the red phosphors within a wavelength range of no less than 550 nm and no more than 600 nm at a temperature of 300 K or more is 1/100 or less of the integrated value of the excitation spectrum of the red phosphors within a wavelength range of no less than 430 nm and no more than 480 nm. The wavelength of the excitation spectrum to be measured is a peak wavelength of the red phosphors. In the description, the “red range” means a range in which the wavelength is no less than 580 nm and less than 700 nm.

The illumination of the red phosphors can hardly be confirmed in a long wavelength range of 700 nm or more. In a long wavelength range of 700 nm or more, the luminosity factor of humans is relatively low. Accordingly, in the case where the light emitting device is used for, for example, illumination, the use of the red phosphors is very advantageous.

The red phosphors do not absorb light within a wavelength range of no less than 550 nm and no more than 600 nm and are unlikely to absorb secondary light from the green phosphors. Thus, two-step illumination, in which the red phosphors absorb secondary light from the green phosphors and illuminate, can be prevented from occurring. Accordingly, a high luminous efficacy can be maintained.

The red phosphors are not particularly limited, provided that the red phosphors can be used for a wavelength-converting portion of the light emitting device. For example, (Sr, Ca)AlSiN₃:Eu phosphors or CaAlSiN₃:Eu phosphors can be used.

### (Green Phosphor)

The green phosphors are excited by primary light emitted from the LED elements and emit light whose peak emission wavelength is in a green range. The green phosphors are not particularly limited, provided that the green phosphors can be used for the wavelength-converting portion of the light emitting device. For example, a phosphor that is expressed by a general formula (1): (M1)₃₋ₓCeₓ(M2)₅O₁₂ can be used (in the formula, (M1) represents at least one of Y, Lu, Gd, and La, (M2) represents at least one of Al and Ga, and x representing a composition ratio (concentration) of Ce satisfies 0.005≦x≦0.20). The “green range” means a range in which the wavelength is no less than 500 nm and no more than 580 nm.

The half width of the fluorescence spectrum of the green phosphors is preferably wide, for example, 95 nm or more in the case where a kind of green phosphor is used (for example, in the case of typical illumination use). A phosphor that uses Ce as an activator, for example, a Lu₃₋ₓCeₓAl₅O₁₂ green phosphor that is expressed by the general formula (1) has a garnet crystal structure. Since this phosphor uses Ce as an activator, a fluorescence spectrum having a wide half width (half width is 95 nm or more) is achieved. Accordingly, the phosphor that uses Ce as an activator is a preferred green phosphor to achieve a high color rendering property.

### (Additive)

The light-emitting portion may include an additive such as SiO₂, TiO₂, ZrO₂, Al₂O₃, or Y₂O₃ in addition to the translucent resin, the green phosphors, and the red phosphors. In the case where the light-emitting portion includes such an additive, settling of the phosphors such as the green phosphors and the red phosphors can be prevented, and light from the LED elements, the green phosphors, and the red phosphors can be efficiently diffused.

### Second Embodiment

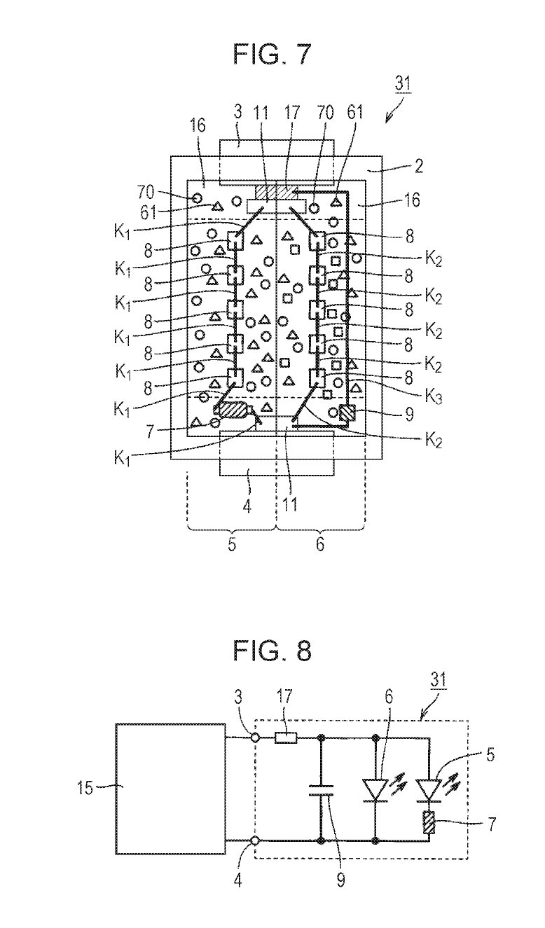

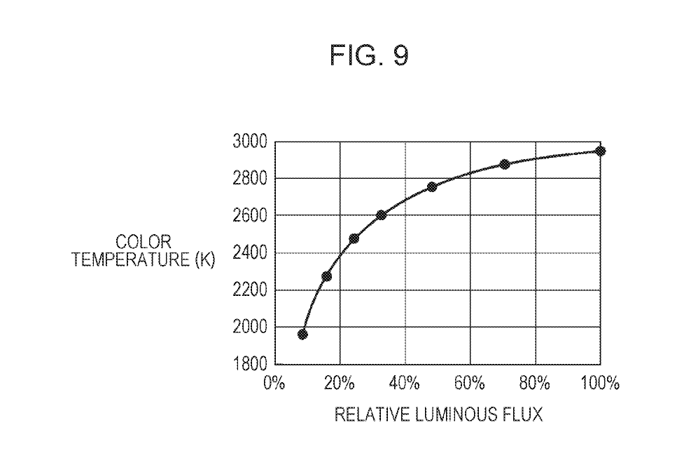

FIG. 7 is a schematic plan view of a light emitting device according to a second embodiment of the present invention. FIG. 8 is a schematic circuit diagram of a lighting device manufactured in a manner in which the light emitting device in FIG. 7 is connected to a PWM signal type dimmer 15.

A light emitting device 31 according to the present embodiment has the same basic structure as the light emitting device 1 according to the first embodiment. A difference from the first embodiment is to include an electrostatic capacity member 9 arranged in parallel with the first light-emitting portion 5 and the second light-emitting portion 6 and a second resistance member 17 arranged in series with the first light-emitting portion 5 and the second light-emitting portion 6. The electrostatic capacity member 9 is electrically connected to one of the leads 11 and the second resistance member 17 with a conductive wiring K₃ interposed therebetween.

In the light emitting device 31, a circuit including the electrostatic capacity member 9 and the second resistance member 17 forms a low-pass filter. Accordingly, as illustrated in FIG. 8, in the case where the light emitting device 31 is connected to the PWM (Pulse Width Modulation) signal type dimmer 15, a pulse signal from the PWM signal type dimmer 15 can be converted into a direct voltage. Thus, the light emitting device 31 can adjust the color temperature of light emitted from the entire light-emitting portion including the light-emitting portion 5 and the light-emitting portion 6 by using the PWM signal type dimmer 15.

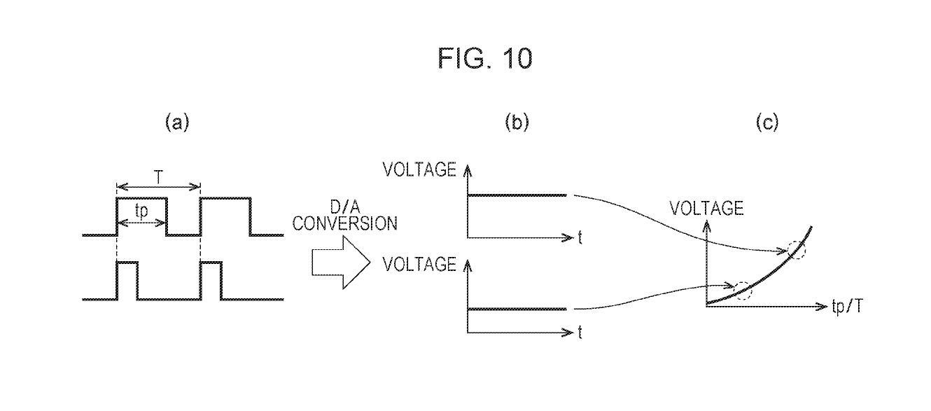

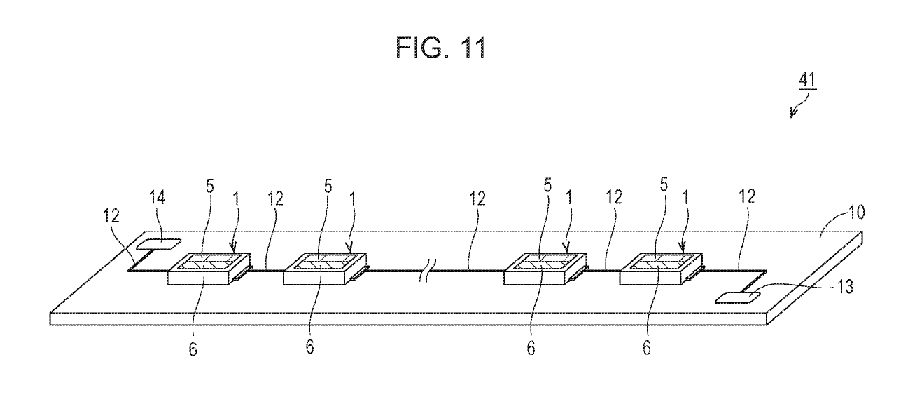

Digital-analog conversion (also referred to below as D/A conversion) in the case where an electric signal of the PWM signal type dimmer passes through the low-pass filter will be described with reference to FIG. 10. A typical lighting device that uses a LED element adjusts light by using a PWM signal type dimmer. Specifically, the PWM signal type dimmer creates a pulse wave as illustrated in FIG. 10(a) and controls the adjustment of light of the lighting device in a manner in which the duty cycle (tp/T) (tp represents a plus width, and T represents a period) of the pulse wave is changed to change a lighting time. Accordingly, the PWM signal type dimmer cannot directly be applied to the light emitting device according to the first embodiment that mixes colors by using a variation in the value of current.

According to the present embodiment, a pulse signal from the PWM signal type dimmer 15 can be D/A converted into a signal of a direct voltage as illustrated in FIG. 10(b) by using the low-pass filter including the electrostatic capacity member 9 and the second resistance member 17. As illustrated in FIG. 10(c), the direct voltage can be changed in a manner in which the duty cycle (tp/T) of the pulse wave created by the PWM signal type dimmer 15 is changed. Thus, according to the present embodiment, the color temperature of light emitted from the entire light-emitting portion including the light-emitting portion 5 and the light-emitting portion 6 can be adjusted by using the PWM signal type dimmer 15.

The electrostatic capacity member 9 may be, for example, a chip capacitor, an electrolytic capacitor, or a film capacitor.

The second resistance member 17 may be a chip resistor or an inductor.

The electrostatic capacity member 9 and the second resistance member 17 may be formed inside the reflector. This enables the size of the light emitting device 31 to be decreased. In addition, absorption of light emitted from the LED elements 8 by the electrostatic capacity member 9 and the second resistance member 17 can be suppressed, and a noise component can be reduced.

### Third Embodiment

A light emitting device according to a third embodiment of the present invention will be described with reference to FIG. 11. A light emitting device 41 includes an anode electrode land 13 and a cathode electrode land 14 that are disposed on a ceramic or metallic substrate 10, wiring patterns 12 that connect the anode electrode land 13 and the cathode electrode land 14 to each other, and five light emitting devices 1 electrically connected in series on the wiring patterns 12. Each light emitting device 1 has the same structure as the light emitting device according to the first embodiment. The five light emitting devices 1 are arranged close to each other to such an extent that light emitted from each light emitting device can be sufficiently mixed, and accordingly, light emitted from the entire light emitting device 41 is light with a uniform color temperature.

In the case where the substrate 10 is a metallic substrate, insulation layers are formed below the anode electrode land 13, the cathode electrode land 14, and the wiring patterns 12. The insulation layers are preferably colored (for example, white or milk white) to reflect light emitted from the LED elements. The shape of the substrate 10 may be any one of a polygon, a circle, and, a rectangle in plan view.

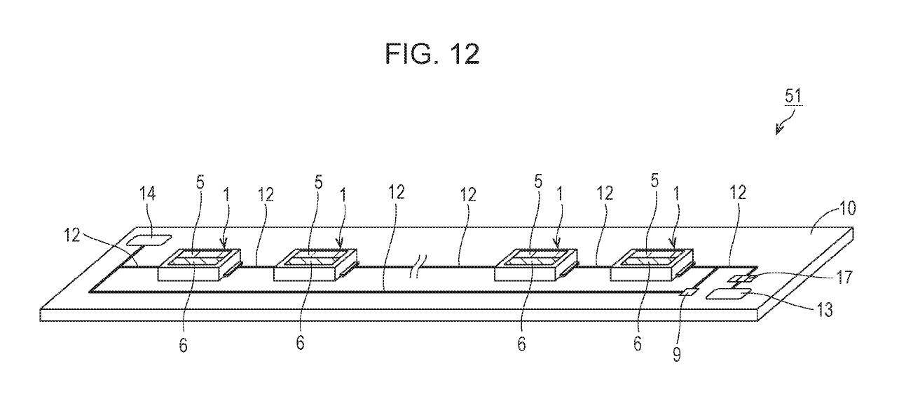

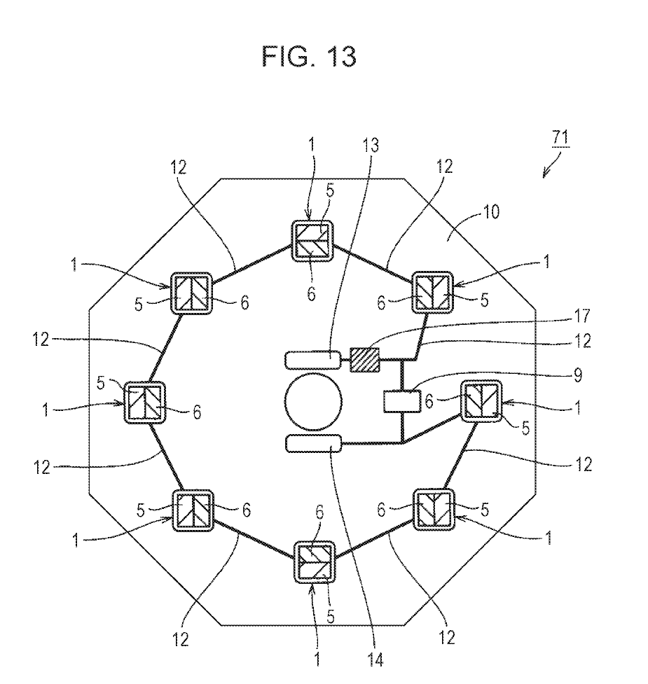

FIG. 12 and FIG. 13 are a perspective view and a plan view of modifications to the light emitting device according to the third embodiment. A light emitting device 51 and a light emitting device 71 according to the modifications have the same basic structure as the light emitting device 41 according to the third embodiment. A difference from the light emitting device 41 according to the third embodiment is to include the electrostatic capacity member 9 arranged in parallel with the five light emitting devices 16 and the second resistance member 17 arranged in series with the five light emitting devices 1. Accordingly, in the case where the light emitting device 51 or the light emitting device 71 is connected to a PWM signal type dimmer, a pulse signal from the PWM signal type dimmer can be converted into a direct voltage. Thus, the light emitting device 51 and the light emitting device 71 can adjust the color temperature of light emitted from the entire light emitting device including the five light emitting devices 1 by using the PWM signal type dimmer.

In the light emitting device 71 illustrated in FIG. 13, a hole for connecting an external power supply wiring to the anode electrode land 13 and the cathode electrode land 14 is formed at a central portion of the substrate 10. The wiring patterns 12 are preferably covered by colored (for example, preferably white or milk white) insulation layers to reflect light emitted from the LED elements.

The present invention is not limited to the above embodiments. Various modifications can be made within the scope shown in claims. Embodiments obtained by appropriately combining technical measures disclosed in the different embodiments are included in the technical scope of the present invention.

### EXAMPLES

The present invention will be described in more detail with reference to examples. The present invention, however, is not limited to the examples.

### Example 1

In an example 1, a light emitting device having the same structure as the light emitting device according to the first embodiment illustrated in FIG. 1 to FIG. 4 was used to conduct an experiment. The reflector 2 is formed of a metallic lead frame and a resin. The first resistance member 7 is a chip resistor having a resistance value of 60Ω.

At the first light-emitting portion 5, the second red phosphors 61 ((Sr, Ca)AlSiN₃:Eu), the green phosphors 70 (Lu₃Al₅O₁₂:Ce), and blue-light-emitting LED elements 8 (emission wavelength of 450 nm) are sealed with a silicone resin. At the second light-emitting portion 6, the first red phosphors 60 (CaAlSiN₃:Eu), the second red phosphors 61 ((Sr, Ca)AlSiN₃:Eu), the green phosphors 70 (Lu₃Al₅O₁₂:Ce), and blue-light-emitting LED elements 8 (emission wavelength of 450 nm) are sealed with a silicone resin. The blue-light-emitting LED elements 8 and the wiring patterns 12 are electrically connected to each other by using wires. The wiring patterns 12 are electrically connected to the anode electrode terminal 3 or the cathode electrode terminal 4. The silicone resin used for the first light-emitting portion 5 is more thixotropic than the silicone resin used for the second light-emitting portion 6. Accordingly, when the light-emitting portion was disposed inside the reflector, the silicone resin for the first light-emitting portion was applied, and the silicone resin for the second light-emitting portion was subsequently applied.

The light emitting device in the example 1 is formed such that the color temperature of light emitted from the first light-emitting portion is 2000 K and the color temperature of light emitted from the second light-emitting portion is 3000 K. Subsequently, the relationship between the total value of the forward current (also referred to below as the total forward current) flowing through the wires K₁ and K₂ and the color temperature of light emitted from the light emitting device was investigated.

The color temperature of light emitted from the entire light emitting device when a total forward current of 350 mA flowed was 2900 K, and the color temperature of the light emitted from the entire light emitting device when a total forward current of 50 mA flowed was 2000 K.

FIG. 5 is a graph illustrating the relationship between the relative luminous flux (%) and color temperature of light when the luminous flux of the light emitted from the entire light emitting device was 100% at a total forward current of 350 mA and the total forward current was varied. It is understood from FIG. 5 that the less the relative luminous flux, the smaller the color temperature. A light spectrum when the color temperature of the light emitted from the entire light emitting device is 2900 K (forward current of 350 mA) and a light spectrum when the color temperature is 2000 K (forward current of 50 mA) demonstrate that the light emitting device in the example 1 can change the color temperature by using power supply from a single power source.

### Example 2

In an example 2, the light emitting device according to the second embodiment illustrated in FIG. 7 was used and a lighting device having the same structure as the lighting device illustrated in FIG. 8 was used to conduct an experiment. In the example 2, a low-pass filter is formed in a manner in which the second resistance member 17, which is electrically connected to one of the leads 11 and the anode electrode terminal 3, and the electrostatic capacity member 9 are electrically connected to and combined with each other with the conductive wiring K₃ interposed therebetween. A cutoff frequency fc is expressed by ½πCR, where C represents the electrostatic capacity of the electrostatic capacity member, and R represents the resistance value of the second resistance member. When the cutoff frequency fc increases with respect to a PWM signal frequency F, a ripple component due to a high frequency component cannot be removed, and a variation in voltage increases. Accordingly, setting is made such that PWM signal frequency F>>cutoff frequency fc holds. In the example 2, a PWM signal is D/A converted when passing through the low-pass filter, and the value of the direct current flowing through the wires K₁ and K₂ can be controlled.

The reflector 2 is formed of a metallic lead frame and a resin. The first resistance member 7 is a chip resistor having a resistance value of 60Ω. The second resistance member 17 is a chip resistor having a resistance value of 10Ω. The electrostatic capacity member 9 is a chip capacitor having an electrostatic capacity of about 100 μF when a PWM frequency is 1 kHz.

At the first light-emitting portion 5, the second red phosphors 61 ((Sr, Ca)AlSiN₃:Eu), the green phosphors 70 (Lu₃Al₅O₁₂:Ce), and the blue-light-emitting LED elements 8 (emission wavelength of 450 nm) are sealed with a silicone resin. At the second light-emitting portion 6, the first red phosphors 60 (CaAlSiN₃:Eu), the second red phosphors 61 ((Sr, Ca)AlSiN₃:Eu), the green phosphors 70 (Lu₃Al₅O₁₂:Ce), and the blue-light-emitting LED elements 8 (emission wavelength of 450 nm) are sealed with a silicone resin. The blue-light-emitting LED elements 8 and the wiring patterns 12 are electrically connected to each other by using the wires K₁. The wiring patterns 12 are electrically connected to the anode electrode terminal 3 or the cathode electrode terminal 4. The silicone resin used for the first light-emitting portion 5 is more thixotropic than the silicone resin used for the second light-emitting portion 6. Accordingly, when the light-emitting portion was disposed inside the reflector, the silicone resin for the first light-emitting portion was applied, and the silicone resin for the second light-emitting portion was subsequently applied.

The light emitting device 31 in the example 2 is formed such that the color temperature of light emitted from the first light-emitting portion is 2000 K and the color temperature of light emitted from the second light-emitting portion is 3000 K. Subsequently, the relationship between the total value of the forward current (also referred to below as the total forward current) flowing through the wires K₁ and K₂ and the color temperature of light emitted from the light emitting device was investigated.

The color temperature of light emitted from the entire light emitting device when a total forward current of 350 mA flowed was 2900 K, and the color temperature of light emitted from the entire light emitting device when a total forward current of 50 mA flowed was 2000 K.

FIG. 9 is a graph illustrating the relationship between the relative luminous flux (%) and color temperature of light when the luminous flux of the light emitted from the entire light emitting device is 100% at a total forward current of 350 mA and the total forward current was varied. It is understood from FIG. 9 that the less the relative luminous flux, the smaller the color temperature. A light spectrum when the color temperature of the light emitted from the entire light emitting device is 2900 K (forward current of 350 mA) and a light spectrum when the color temperature is 2000 K (forward current of 50 mA) demonstrate that the light emitting device in the example 2 can change the color temperature by using power supply from a single power source.

It should be understood that the embodiments and examples are disclosed by way of example in all aspects and are not restrictive. It is intended that the scope of the present invention is not shown by the above embodiments but is shown by claims and contains all modifications having the same content and scope as the claims.

### REFERENCE SIGNS LIST

1, 21, 31, 41, 51, 71 light emitting device
2 reflector
3 anode electrode terminal
4 cathode electrode terminal
5 first light-emitting portion
6 second light-emitting portion
7 first resistance member
8 LED element
9 electrostatic capacity member
10 substrate
11 lead
12 wiring pattern
13 anode electrode land
14 cathode electrode land
15 PWM signal type dimmer
16 translucent resin
17 second resistance member
60 first red phosphor
61 second red phosphor
70 green phosphor
K₁, K₂ wire
K₃ conductive wiring.

1. A light emitting device, comprising:
a resin reflector formed of a housing having an opening at an upper portion;
anode electrode terminal and a cathode electrode terminal that are disposed on a side wall or a bottom surface of the housing; and
a first light-emitting portion on which light-emitting elements are mounted and a second light-emitting portion on which light-emitting elements are mounted, the first light-emitting portion and the second light-emitting portion being arranged in parallel inside the reflector so as to be electrically connected to the anode electrode terminal and the cathode electrode terminal and being adjacent to each other,
wherein the first light-emitting portion includes a first resistance member, and
wherein the first light-emitting portion and the second light-emitting portion are covered by resin members that are made of a resin containing a phosphor and that are adjacent to each other inside the reflector,
wherein a color temperature of light emitted from the opening of the reflector in which the first light-emitting portion and the second light-emitting portion are formed can be adjusted by using power supply from a single power source,
wherein the first light-emitting portion and the second light-emitting portion each include a LED element that emits blue light whose peak wavelength is 430 to 480 nm, a translucent resin, and a phosphor, and
wherein the phosphor included in the first light-emitting portion and the phosphor included in the second light-emitting portion each include a red phosphor that is excited by primary light emitted from the corresponding LED element and that emits light whose peak emission wavelength is in a red range and a green phosphor that is excited by primary light emitted from the corresponding LED element and that emits light whose peak emission wavelength is in a green range.

2. The light emitting device according to claim 1,
wherein the first light-emitting portion and the second light-emitting portion are each arranged on a lead frame or a ceramic.

3. The light emitting device according to claim 1, further comprising:
an electrostatic capacity member arranged in parallel with the first light-emitting portion and the second light-emitting portion; and
a second resistance member arranged in series with the first light-emitting portion and the second light-emitting portion.

4. The light emitting device according to claim 3,
wherein the second resistance member is a resistor or an inductor.

5. A lighting device, comprising:
the light emitting device according to claim 1; and
a PWM signal type dimmer electrically connected to the light emitting device.
